(19) United States
(12) Patent Application Publication
(10) Pub. No.: US 2024/0321652 A1
(43) Pub. Date: Sep. 26, 2024

(54) DISPLAY APPARATUS

(71) Applicant: Samsung Display Co., Ltd., Yongin-si (KR)

(72) Inventor: Taesoo Kang, Yongin-si (KR)

(73) Assignee: Samsung Display Co., Ltd., Yongin-si (KR)

(21) Appl. No.: 18/612,205

(22) Filed: Mar. 21, 2024

(30) Foreign Application Priority Data
Mar. 24, 2023 (KR) 10-2023-0039128
Aug. 10, 2023 (KR) 10-2023-0105090

(51) Int. Cl. H01L 21/66; G01R 31/28; H10K 59/131

(52) U.S. Cl. CPC H01L 22/32; G01R 31/2884; H10K 59/131

(57) ABSTRACT

A display apparatus includes a first area including a display area, a second area, and a bending area between the first area and the second area, a substrate, a display element in the display area of the substrate, a first line extending to surround at least a portion of the display area, a first test pad, a second test pad, and a third test pad, disposed in the second area, a first test line electrically connected to the first line in the second area and electrically connected to the first test pad, a second test line extending through the bending area, electrically connected to the first line in the first area, and electrically connected to the second test pad, and a third test line spaced apart from the first test line, electrically connected to the first line in the second area, and electrically connected to the third test pad.

### CROSS-REFERENCE TO RELATED APPLICATION(S)

This application claims priority to and benefits of Korean Patent Application Nos. 10-2023-0039128, filed on Mar. 24, 2023, and 10-2023-0105090, filed on Aug. 10, 2023 under 35 U.S.C. § 119, in the Korean Intellectual Property Office, the entire contents of which are incorporated herein by reference.

### BACKGROUND

### 1. Technical Field

One or more embodiments relate to display apparatuses.

### 2. Description of the Related Art

Display apparatuses visually display data. Display apparatuses are used as displays for small products such as mobile phones, and are also used as displays for large products such as televisions.

Each of the display apparatuses may include a substrate divided into a display area and a non-display area, and gate lines and data lines that are insulated from each other are formed in the display area. Sub-pixel regions are defined in the display area, and sub-pixels arranged in each of the sub-pixel regions emit light by receiving electrical signals from gate lines and data lines, which intersect each other, to display images to the outside. Each of the sub-pixel regions is provided with a thin-film transistor and a sub-pixel electrode electrically connected to the thin-film transistor, and an opposite electrode is commonly provided in the sub-pixel regions. The non-display area may be provided with various wiring lines that transmit electrical signals to sub-pixels in the display area, a gate driver, and pads to which a data driver and a controller may be connected.

Recently, the uses of display apparatuses have been diversified. As the display apparatuses become thinner and lighter, and the scope of their uses is expanding. For example, cracks may readily occur in display apparatuses due to external forces in case that the display apparatuses are moved or handled. Moisture or oxygen introduced from the outside through the cracks may reach organic light-emitting diodes in the display apparatuses. The organic light-emitting diodes may be readily oxidized, which may result in reduced reliability. Therefore, the importance of research on predicting and detecting whether cracks in display apparatuses will occur is increasing, and research related to this is actively being conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus in which detection of a crack is possible in a non-driving state. Embodiments set forth herein are examples, and embodiments of the disclosure are not limited thereto.

Additional aspects will be set forth in part in the description which follows and, in part, will be apparent from the description, or may be learned by practice of the presented embodiments of the disclosure.

According to one or more embodiments, a display apparatus may include a first area including a display area, a second area, and a bending area disposed between the first area and the second area; a substrate; a display element disposed in the display area of the substrate; a first line extending to surround at least a portion of the display area; a first test pad, a second test pad, and a third test pad disposed in the second area; a first test line electrically connected to the first line in the second area and electrically connected to the first test pad; a second test line extending through the bending area, the second test line being electrically connected to the first line in the first area, and the second test line being electrically connected to the second test pad; and a third test line spaced apart from the first test line, the third test line being electrically connected to the first line in the second area, and the third test line being electrically connected to the third test pad.

The substrate may be bent in the bending area, and a back surface of the second area faces at least a portion of a back surface of the first area.

The display apparatus may further include a fourth test pad disposed in the second area; and a fourth test line extending through the bending area, the fourth test line being electrically connected to the first line in the first area, and the fourth test line being electrically connected to the fourth test pad.

The first test line and the second test line may be disposed on a side of the substrate, and the third test line and the fourth test line may be disposed on another side of the substrate opposite to the side of the substrate.

The first line, the first test line, the second test line, and the third test line may be integral with each other.

The substrate may have a through hole included in the first area, and the display apparatus may further include a through-hole detection line electrically connected to the first line and adjacent to the through hole; and a second line electrically connected to the through-hole detection line and extending to surround at least a portion of the display area.

The through-hole detection line may have a shape that surrounds or dually surrounds the through hole.

The first line may be disposed outside of the second line.

The first line may include a 1st-1 line extending along an edge of the substrate and a 1st-2 line extending along another edge of the substrate, and the second line may include a 2nd-1 line extending along an edge of the substrate and a 2nd-2 line extending along another edge of the substrate.

The display apparatus may further include a first pad disposed in the second area; a first voltage line electrically connected to the first pad; and a second voltage line electrically connected to the 2nd-1 line.

The 1st-1 line may be electrically connected to the first pad.

The display apparatus may further include a first data line and a second data line disposed in the display area and each of the first data line and the second data line extending in a first direction; a first transistor electrically connected between the first voltage line and the first data line; and a second transistor electrically connected between the second voltage line and the second data line.

The first transistor and the second transistor may be simultaneously controlled.

The display apparatus may further include a second pad disposed in the second area; a third voltage line electrically connected to the second pad; and a fourth voltage line electrically connected to the 2nd-2 line.

The 2nd-1 line may be electrically connected to the second pad.

The display apparatus may further include a third data line and a fourth data line disposed in the display area and each of the third data line and the fourth data line extending in a first direction; a third transistor electrically connected between the third voltage line and the third data line; and a fourth transistor electrically connected between the fourth voltage line and the fourth data line.

The third transistor and the fourth transistor may be simultaneously controlled.

The display apparatus may further include a fourth test pad disposed in the second area; and a fourth test line extending through the bending area, the fourth test line being electrically connected to the first line in the first area, and the fourth test line being electrically connected to the fourth test pad.

The first test line and the second test line may be electrically connected to the 1st-1 line, and the third test line and the fourth test line may be electrically connected to the 1st-2 line.

The first test line and the second test line may be disposed on a side of the substrate, and the third test line and the fourth test line may be disposed on another side of the substrate opposite to the side of the substrate.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic plan view of a display apparatus according to an embodiment;

FIG. 2 is a schematic side view of a display apparatus according to an embodiment;

FIG. 3 is a schematic diagram of an equivalent circuit of a sub-pixel according to an embodiment;

FIG. 4 is a schematic cross-sectional view of a portion of a display apparatus according to an embodiment;

FIG. 5 is a schematic plan view of a display apparatus according to an embodiment;

FIG. 6 is a schematic side view of a display apparatus according to an embodiment;

FIG. 7 is an enlarged schematic plan view schematically showing a portion of the display apparatus of FIG. 5; and

FIG. 8 is an enlarged schematic plan view schematically showing a portion of the display apparatus of FIG. 5.

### DETAILED DESCRIPTION OF THE EMBODIMENTS

Reference will now be made in detail to embodiments, examples of which are illustrated in the accompanying drawings, wherein like reference numerals refer to like elements throughout. In this regard, embodiments may have different forms and should not be construed as being limited to the descriptions set forth herein. Accordingly, the embodiments are described below, by referring to the figures, to explain aspects of the description.

In the drawings, sizes, thicknesses, ratios, and dimensions of the elements may be exaggerated for ease of description and for clarity. Like numbers refer to like elements throughout.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the embodiments, and example embodiments will be illustrated in the drawings and described in the detailed description section. The effects and features of the embodiments, and a method to achieve the same, will be clearer referring to the detailed descriptions below with the drawings. However, the embodiments may be implemented in various forms, not by being limited to the embodiments presented below.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms are intended to include the plural forms as well, unless the context clearly indicates otherwise.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when a layer, region, or component is referred to as being “formed on” another layer, region, or component, it can be directly or indirectly formed on the other layer, region, or component. For example, intervening layers, regions, or components may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element, a case in which a third element intervenes between the first and second element, the first and second element may be understood as being indirectly opposed to one another, although still facing each other.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As used herein, when a wiring is referred to as “extending in a first direction or a second direction,” it means that the wiring not only extends in a straight line shape but also extends in a zigzag or in a curve in the first direction or the second direction.

As used herein, “in a plan view” means that an objective portion is viewed from above, and “in a cross-sectional view” means that a cross-section of an objective portion taken vertically is viewed from a lateral side. As used herein, “overlapping” includes overlapping “in a plan view” and “in a cross-sectional view.”

Hereinafter, embodiments of the disclosure are described in detail with reference to the accompanying drawings. When description is made with reference to the drawings, like reference numerals are used for like or corresponding elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains, will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

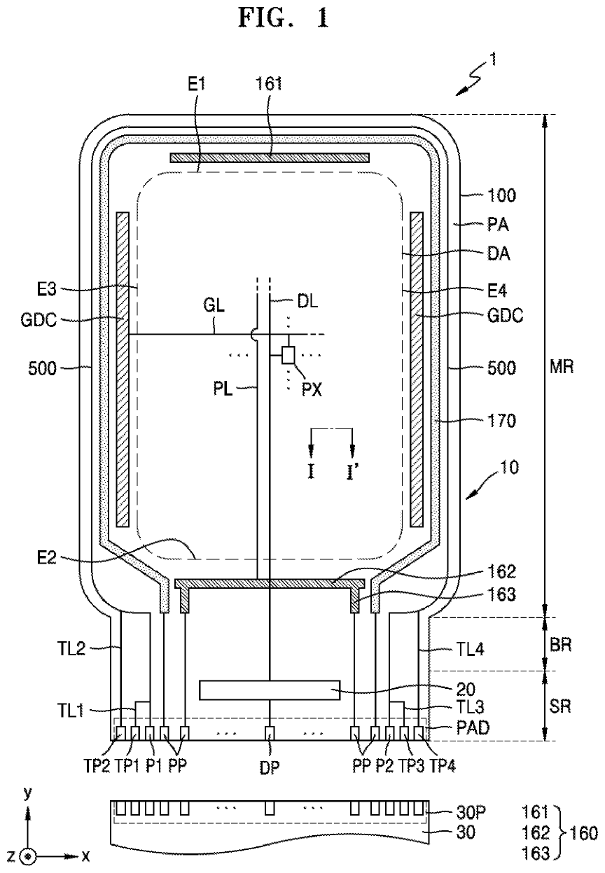

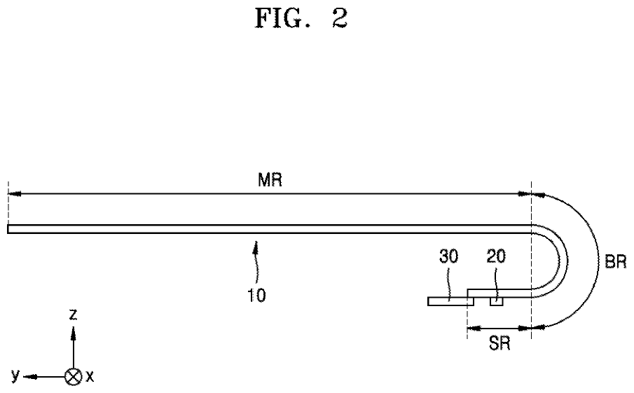

FIG. 1 is a schematic plan view of a display apparatus 1 according to an embodiment, and FIG. 2 is a schematic side view of a display apparatus 1 according to an embodiment.

Although a portion of the display apparatus 1 according to an embodiment is bent, it is shown in FIG. 1 that the display apparatus 1 is not bent, for convenience.

Referring to FIG. 1, the display apparatus 1 may include a display panel 10. The display apparatus 1 may be any device that may include the display panel 10. For example, the display apparatus 1 may be a variety of products, such as a smartphone, tablet, laptop, television, or billboard.

The display panel 10 may include a display area DA and a peripheral area PA outside of the display area (DA). As shown in FIG. 1, the peripheral area PA may be arranged (or disposed) to surround the display area DA. Because the display panel 10 may include a substrate 100, it may be said that the substrate 100 has the display area DA and the peripheral area PA.

The display panel 10 may include a main area MR, a bending area BR outside of the main area MR, and a sub-area SR located (or disposed) on the opposite side of the main area MR with the bending area BR as the center. The main area MR may include the display area DA. The sub-area SR may correspond to one side or a side of the peripheral area PA. In an embodiment, the main area MR may be a first area and the sub-area SR may be a second area.

The edges of the display area DA may have an overall shape similar to a rectangle or square. The display area DA may have a first edge E1 and a second edge E2 facing each other, and a third edge E3 and a fourth edge E4 facing each other and located between the first edge E1 and the second edge E2. The bending area BR and the sub-area SR may be adjacent to the second edge E2 of the display area DA.

As shown in FIG. 2, the substrate 100 and the display panel 10 may be bent in the bending area BR. In case that the bent display panel 10 is viewed in a z direction, at least a portion of the sub-area SR may overlap the main area MR. By bending, the rear surface of the sub-area SR may face at least a portion of the rear surface of the main area MR. However, the disclosure is not limited to the bent display apparatus 1 and may also be applied to a non-bended display apparatus 1. The sub-area SR may be a non-display area. By bending the display panel 10 in the bending area BR, in case that the display apparatus 1 is viewed from the front (in a −z direction), the non-display area may not be visible, or even if it is visible, a visible area may be reduced.

A driving chip 20 may be arranged in the sub-area SR of the display panel 10. The driving chip 20 may include an integrated circuit that drives the display panel 10. The integrated circuit may be a data driving integrated circuit that generates a data signal, but the disclosure is not limited thereto.

The driving chip 20 may be mounted in the sub-area SR of the display panel 10. The driving chip 20 may be mounted on the same surface as the display surface of the display area DA. However, as the display panel 10 is bent in the bending area BR as described above, the driving chip 20 may be located on the back of the main area MR.

A printed circuit board 30 and the like may be attached to an end of the sub-area SR of the display panel 10. The printed circuit board 30 and the like may be electrically connected to the driving chip 20 or the like through pads on the substrate 100. FIG. 1 illustrates that the driving chip 20 is disposed on the sub-area SR. However, as another example, the driving chip 20 may be disposed on the printed circuit board 30.

The display panel 10 may include sub-pixels PX arranged in the display area DA, and each of the sub-pixels PX may include a display element. The disclosure is explained using an organic light-emitting diode as an example as a display element. The organic light-emitting diode of each sub-pixel PX may emit, for example, red, green, blue, or white light.

Each of sub-pixel circuits that drive the sub-pixels PX may be connected to a signal line or voltage line for controlling a display element. For example, FIG. 1 shows a gate line GL extending in a first direction (for example, x direction) and a data line DL extending in a second direction (for example, ±y direction) as signal lines and shows a driving voltage line PL as a voltage line.

Each sub-pixel PX may be electrically connected to external circuits arranged in the peripheral area PA. For example, a driving voltage supply line 160, a common voltage supply line 170, a gate driving circuit GDC, and a pad portion PAD may be arranged in the peripheral area PA.

The driving voltage supply line 160 may include a first sub-line 161 and a second sub-line 162 extending in parallel in the first direction (for example, ±x direction) with the display area DA therebetween, and a third sub-line 163 extending from the second sub-line 162 in the second direction (for example, −y direction) and may supply a driving voltage (for example, ELVDD). The driving voltage may be provided to the sub-pixel circuit of each sub-pixel PX through the driving voltage line PL connected to the driving voltage supply line 160. The common voltage supply line 170 that partially surrounds the display area DA may be disposed on the peripheral area PA. For example, the common voltage supply line 170 may have a loop shape open toward the pad portion PAD. A common voltage (for example, ELVSS) may be transmitted to the common voltage supply line 170, and the common voltage may be provided to the opposite electrode of each sub-pixel PX connected to the common voltage supply line 170.

The gate driving circuit GDC may be connected to gate lines GL extending in the first direction (for example, ±x direction). The gate lines GL may be each connected to sub-pixels PX located in the same row and may sequentially transmit electrical signals. The gate driving circuit GDC may include a scan driving circuit and an emission control driving circuit. The scan driving circuit included in the gate driving circuit GDC may provide a scan signal to each sub-pixel PX through a scan line. The emission control driving circuit included in the gate driving circuit GDC may provide an emission control signal to each sub-pixel PX through an emission control line.

FIG. 1 illustrates that the gate driving circuit GDC is disposed on the left side of the display panel 10. However, as another example, the gate driving circuit GDC may be disposed on the right side of the display panel 10. As another example, there may be gate driving circuits GDC. The gate driving circuits GDC may be disposed on the left and right sides of the display panel 10, respectively, with the display area DA therebetween.

The pad portion PAD may be disposed on one side or a side (for example, lower or bottom portion) of the peripheral area PA. For example, the pad portion PAD may be disposed at an end of the sub-area SR of the display panel 10, as shown in FIG. 1.

Various electronic devices, the printed circuit board 30, and the like may be electrically attached to the pad portion PAD. The pad portion PAD may be exposed without being covered by an insulating layer and be electrically connected to the printed circuit board 30. A terminal portion 30P of the printed circuit board 30 may be electrically connected to the pad portion PAD of the display panel 10. The printed circuit board 30 may be directly coupled or connected to the display panel 10 or may be connected to the display panel 10 through another circuit board.

The pad portion PAD may include a data pad DP, a voltage supply pad PP, a first pad P1, a second pad P2, a first test pad TP1, a second test pad TP2, a third test pad TP3, and a fourth test pad TP4. The data pad DP, the voltage supply pad PP, the first pad P1, the second pad P2, and the first to fourth test pads TP1, TP2, TP3, and TP4 may be apart from each other and may be arranged in the first direction (for example, ±x direction).

The data pad DP may be connected to a data line DL extending in the second direction (for example, ±y direction). The data line DL may be connected to sub-pixels PX located in the same column and may sequentially transmit electrical signals. The data line DL may be connected to the driving chip 20. In an embodiment, the data line DL may be electrically connected to the data pad DP via the driving chip 20. As described above, the driving chip 20 may include a data driving integrated circuit that generates a data signal, and the driving chip 20 may provide a data signal to each sub-pixel PX through the data line DL.

The voltage supply pad PP may be electrically connected to the driving voltage supply line 160 and/or the common voltage supply line 170. The voltage supply pad PP may provide a driving voltage provided from the outside to the driving voltage supply line 160. The voltage supply pad PP may provide a common voltage provided from the outside to the common voltage supply line 170. The number and arrangement of data pads DP and voltage supply pads PP are not limited to that shown in FIG. 1.

A first line 500, a first test line TL1, a second test line TL2, a third test line TL3, and a fourth test line TL4 may be arranged in the peripheral area PA.

The first line 500 may be arranged in the peripheral area PA and may extend to surround at least a portion of the display area DA. For example, the first line 500 may extend along the first edge E1, third edge E3, and fourth edge E4 of the display area DA. Both ends of the first line 500 surrounding at least a portion of the display area DA may extend to pass through the bending area BR in a direction toward the pad area PAD.

In an embodiment, the first line 500 may be electrically connected to the pad portion PAD, as shown in FIG. 1. The first pad P1 and the second pad P2 may be electrically connected to the first line 500. The first pad P1 may be placed on one side or a side (for example, left side) of the pad portion PAD, and the second pad P2 may be placed on the other side or another side (for example, right side) of the pad portion PAD. However, the disclosure is not limited thereto. In an embodiment, both ends of the first line 500 may be electrically connected to a driving circuit or the driving chip 20, etc.

In an embodiment, the first line 500 may be a line that functions in a driving state of the display apparatus 1. For example, the first line 500 may be a guard ring line provided in a touch sensor layer 400, which will be described later. The guard ring line may prevent the touch sensor layer 400 from malfunctioning or an internal circuit from being damaged by static electricity applied from the outside. The first pad P1 and the second pad P2 electrically connected to the first line 500 may be connected to ground power. By way of example, the first line 500 may be a line for detecting cracks in the display panel 10 while the display apparatus 1 is in a driving state. The first line 500 may be electrically connected to a crack test circuit that operates in a driving state of the display apparatus 1.

The first to fourth test pads TP1, TP2, TP3, and TP4 may be connected to the first test line TL1, the second test line TL2, the third test line TL3, and the fourth test line TL4, respectively. The first test pad TP1 and the second test pad TP2 may be disposed on one side or a side (for example, left side) of the pad portion PAD, and the third test pad TP3 and the fourth test pad TP4 may be disposed on the other side or another side (for example, right side) of the pad portion PAD. The first to fourth test pads TP1, TP2, TP3, and TP4 may be electrically connected to the printed circuit board 30 and may transmit signals transmitted from the printed circuit board 30 to the first to fourth test lines TL1, TL2, TL3, and TL4. As another example, the first to fourth test pads TP1, TP2, TP3, and TP4 may be electrically connected to a separate test circuit board before attaching the printed circuit board 30. The first to fourth test pads TP1, TP2, TP3, and TP4 may transmit signals transmitted from the test circuit board to the first to fourth test lines TL1, TL2, TL3, and TL4. The first to fourth test pads TP1, TP2, TP3, and TP4 may be pads for transmitting test signals or measuring loop resistance.

The first to fourth test lines TL1, TL2, TL3, and TL4 may be electrically connected to the first line 500. The first test line TL1 and the second test line TL2 may be disposed on one side or a side (for example, left side) of the substrate 100, and the third test line TL3 and the fourth test line TL4 may be disposed on the other side or another side (for example, right side) of the substrate 100, which is opposite to the one side (for example, left side) of the substrate 100.

The first test line TL1 may be electrically connected to one side or a side (for example, left side) of the first line 500 in the sub-area SR, for example, between the bending area BR and the pad portion PAD. The first test line TL1 may be electrically connected to the first test pad TP1. The first test line TL1 may electrically connect the first line 500 to the first test pad TP1.

The second test line TL2 may extend from the pad portion PAD toward the display area DA to pass through the bending area BR. The second test line TL2 may be electrically connected to one side or a side (for example, left side) of the first line 500 in the main area MR, for example, between the bending area BR and the display area DA. The second test line TL2 may be electrically connected to the second test pad TP2. The second test line TL2 may electrically connect the first line 500 to the second test pad TP2.

The third test line TL3 may be electrically connected to the other side or another side (for example, right side) of the first line 500 in the sub-area SR, for example, between the bending area BR and the pad portion PAD. The third test line TL3 may be electrically connected to the third test pad TP3. The third test line TL3 may electrically connect the first line 500 to the third test pad TP3.

The fourth test line TL4 may extend from the pad portion PAD toward the display area DA to pass through the bending area BR. The fourth test line TL4 may be electrically connected to the other side or another side (for example, right side) of the first line 500 in the main area MR, for example, between the bending area BR and the display area DA. The fourth test line TL4 may be electrically connected to the fourth test pad TP4. The fourth test line TL4 may electrically connect the first line 500 to the fourth test pad TP4.

In an embodiment, the first test line TL1, the second test line TL2, the third test line TL3, and the fourth test line TL4 may be disposed on the same layer as the first line 500 and may include the same material as the first line 500. The first test line TL1, the second test line TL2, the third test line TL3, and the fourth test line TL4 may be integral with the first line 500. However, the disclosure is not limited thereto. In an embodiment, at least some of the first test line TL1, the second test line TL2, the third test line TL3, and the fourth test line TL4 may be disposed on a different layer from the first line 500 and may include a different material from the first line 500.

In this way, whether a crack has occurred in the display apparatus 1 may be checked through the first to fourth test lines TL1, TL2, TL3, and TL4 and the first to fourth test pads TP1, TP2, TP3, and TP4, connected to the first line 500.

For example, the first test line TL1, a portion of the first line 500, and the third test line TL3 may be connected to each other to surround the display area DA and may form a first pattern having a loop shape with one side or a side open. The loop resistance value of the first pattern may be measured through the first test pad TP1 and the third test pad TP3. In case that a crack occurs in the portion of the first line 500, the first test line TL1, and the third test line TL3, which form the first pattern, the resistance value of the first pattern may be measured to be greater than a preset resistance value. Whether a crack has occurred in the display apparatus 1 may be checked through a change in the resistance value of the first pattern.

The first test line TL1, a portion of the first line 500, and the second test line TL2 may be connected to each other and form a second pattern in the form of a loop that passes through the left bending area BR and is open on one side or a side. The loop resistance value of the second pattern may be measured through the first test pad TP1 and the second test pad TP2. In case that a crack occurs in the portion of the first line 500, the first test line TL1, and the second test line TL2, which form the second pattern, the resistance value of the second pattern may be measured to be greater than a preset resistance value. Through the change in the resistance value of the second pattern, it may be checked whether a crack has occurred in the bending area BR of the display apparatus 1, by way of example, in the left bending area BR.

The third test line TL3, a portion of the first line 500, and the fourth test line TL4 may be connected to each other and form a third pattern in the form of a loop that passes through the right bending area BR and is open on one side or a side. The loop resistance value of the third pattern may be measured through the third test pad TP3 and the fourth test pad TP4. In case that a crack occurs in the portion of the first line 500, the third test line TL3, and the fourth test line TL4, which form the third pattern, the resistance value of the third pattern may be measured to be greater than a preset resistance value. Through the change in the resistance value of the third pattern, it may be checked whether a crack has occurred in the bending area BR of the display apparatus 1, by way of example, in the right bending area BR.

As the display apparatus 1 according to an embodiment may include the first line 500 surrounding the display area DA and the first to fourth test lines TL1, TL2, TL3, and TL4 and first to fourth test pads TP1, TP2, TP3, and TP4 connected to the first line 500, it may be checked whether a crack has occurred in the display apparatus 1 in a non-driving state. For example, it may be checked whether a crack has occurred in the left or right bending area BR of the display apparatus 1 in a non-driving state. By measuring the loop resistance through the first to fourth test pads TP1, TP2, TP3, and TP4 during the process of manufacturing the display apparatus 1, it may be checked whether a crack has occurred in the display apparatus 1 on a process basis.

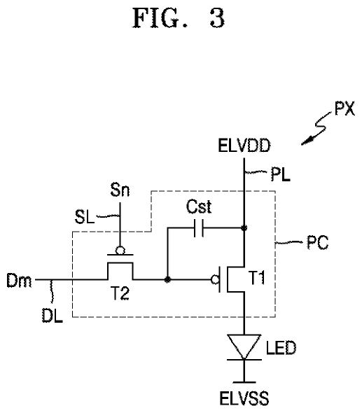

FIG. 3 is a schematic diagram of an equivalent circuit of a sub-pixel PX according to an embodiment.

Referring to FIG. 3, the sub-pixel PX may include a sub-pixel circuit PC and a light-emitting element LED electrically connected to the sub-pixel circuit PC. The sub-pixel circuit PC may include a driving transistor T1, a switching transistor T2, and a storage capacitor Cst. The sub-pixel PX may emit, for example, red, green, or blue light, or may emit red, green, blue, or white light, through the light-emitting element LED.

The switching transistor T2 may be connected to a scan line SL and a data line DL and may transfer a data voltage or data signal Dm input from the data line DL to the driving transistor T1 according to a scan voltage or scan signal Sn input from the scan line SL.

The storage capacitor Cst may be connected to the switching transistor T2 and a driving voltage line PL and may store a voltage corresponding to the difference between a voltage received from the switching transistor T2 and a driving voltage ELVDD supplied to the driving voltage line PL.

The driving transistor T1 may be connected to the driving voltage line PL and the storage capacitor Cst and may control driving current flowing from the driving voltage line PL to the light-emitting element LED in response to a voltage value stored in the storage capacitor Cst. The light-emitting element LED may emit light with a certain (or given) brightness based on the driving current. An opposing electrode (for example, cathode) of the light-emitting element LED may be supplied with a common voltage ELVSS.

FIG. 3 shows that the sub-pixel circuit PC may include two transistors and one storage capacitor. However, in an embodiment, the sub-pixel circuit PC may include three or more transistors.

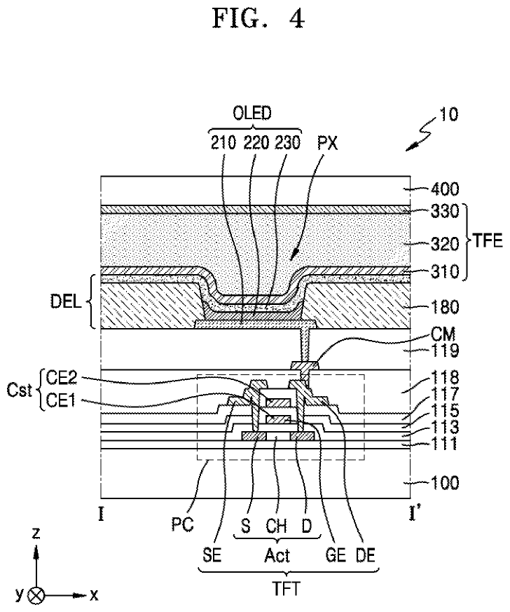

FIG. 4 is a schematic cross-sectional view of a portion of a display apparatus according to an embodiment.

Referring to FIG. 4, a display panel 10 may include a substrate 100, a sub-pixel circuit layer, a light-emitting diode layer DEL, an encapsulation layer TFE, and a touch sensor layer 400. An optical functional layer (not shown), a cover window (not shown), etc. may be further disposed on the touch sensor layer 400.

The substrate 100 may include various materials that are flexible or bendable. For example, the substrate 100 may include a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP).

The sub-pixel circuit layer may be disposed on the substrate 100. The sub-pixel circuit layer may include a sub-pixel circuit PC, an inorganic insulating layer, and an organic insulating layer. In an embodiment, the inorganic insulating layer may include a buffer layer 111, a gate insulating layer 113, a first interlayer insulating layer 115, and a second interlayer insulating layer 117. In an embodiment, the organic insulating layer may include a first organic insulating layer 118 and a second organic insulating layer 119.

The sub-pixel circuit layer may include thin-film transistors and capacitors. In this regard, FIG. 4 shows a thin-film transistor TFT and a storage capacitor Cst. The thin-film transistor TFT may correspond to any one of the thin-film transistors provided in the sub-pixel circuit PC described with reference to FIG. 3, for example, the driving transistor T1. The thin-film transistor TFT may include a semiconductor layer Act, a source electrode SE, a gate electrode GE, and a drain electrode DE.

The buffer layer 111 may be located on the substrate 100 and reduce or block penetration of foreign materials, moisture, or external air from the bottom of the substrate 100 and may provide a flat surface on the substrate 100. The buffer layer 111 may include an inorganic material, such as oxide or nitride, an organic material, or an organic-inorganic composite, and may have a single-layered or multi-layered structure including an inorganic material and an organic material.

The semiconductor layer Ac may include a channel region CH overlapping the gate electrode GE, and a source region S and a drain region D, which are disposed on both sides of the channel region CH and include a higher concentration of impurities than the channel region CH. The impurities may include N-type impurities or P-type impurities. The source region S and the drain region D may be electrically connected to a source electrode SE and a drain electrode DE of the thin-film transistor TFT, respectively.

The semiconductor layer Act may include an oxide semiconductor and/or a silicon semiconductor. In case that the semiconductor layer Act may include an oxide semiconductor, the oxide semiconductor may include, for example, an oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may include InSnZnO (ITZO), InGaZnO (IGZO), etc. In case that the semiconductor layer Act may include a silicon semiconductor, the silicon semiconductor may include, for example, amorphous silicon or low temperature poly-silicon (LTPS) obtained by crystallizing amorphous silicon.

The gate electrode GE may include a conductive material including molybdenum (Mo), aluminum (Al), copper (Cu), titanium (Ti), etc. and may include multiple layers or a single layer including the aforementioned conductive material. The gate electrode GE may be connected to a gate line that applies an electrical signal to the gate electrode GE.

The gate insulating layer 113 may be disposed between the semiconductor layer Act and the gate electrode GE, and thus, the semiconductor layer Act and the gate electrode GE may be insulated from each other. The gate insulating layer 113 may include at least one inorganic insulating material selected from the group including silicon oxide, silicon nitride, silicon oxynitride, aluminum oxide, titanium oxide, tantalum oxide, hafnium oxide, and zinc oxide. The gate insulating layer 113 may have a single-layered or multi-layered structure including the aforementioned inorganic insulating material.

The storage capacitor Cst may include a first capacitor electrode CE1 and a second capacitor electrode CE2 disposed on the first capacitor electrode CE1. The first capacitor electrode CE1 and the second capacitor electrode CE2 of the storage capacitor Cst may be arranged to overlap each other. In an embodiment, the gate electrode GE of the thin-film transistor TFT may include the first capacitor electrode CE1 of the storage capacitor Cst.

The first interlayer insulating layer 115 may be disposed between the first capacitor electrode CE1 and the second capacitor electrode CE2. The first interlayer insulating layer 115 may include an inorganic insulating material, such as silicon oxide, silicon nitride, silicon oxynitride, aluminum oxide, titanium oxide, tantalum oxide, hafnium oxide, and/or zinc oxide, and may have a single-layered or multi-layered structure including the aforementioned inorganic insulating material.

FIG. 4 shows a case where the storage capacitor Cst overlaps the thin-film transistor TFT and the first capacitor electrode CE1 is integral with the gate electrode GE of the thin-film transistor TFT. However, in an embodiment, the storage capacitor Cst may not overlap the thin-film transistor TFT, and the first capacitor electrode CE1 may be an independent component separate from the gate electrode GE of the thin-film transistor TFT.

The second interlayer insulating layer 117 may be disposed on the second capacitor electrode CE2 of the storage capacitor Cst. The second interlayer insulating layer 117 may include at least one inorganic insulating material selected from the group including silicon oxide, silicon nitride, silicon oxynitride, aluminum oxide, titanium oxide, tantalum oxide, hafnium oxide, and zinc oxide. The second interlayer insulating layer 117 may have a single-layered or multi-layered structure including the aforementioned inorganic insulating material.

The source electrode SE and the drain electrode DE may be disposed on the second interlayer insulating layer 117. Each of the source electrode SE and the drain electrode DE may include a material, such as Mo, Al, Cu, and/or Ti, and may have a single-layered or multi-layered structure including the aforementioned material. Each of the source electrode SE and the drain electrode DE may have a multi-layered structure including Ti/Al/Ti layers. In an embodiment, the source electrode SE and the drain electrode DE may include the same material as the driving voltage supply line 160 and the common voltage supply line 170.

A light-emitting diode layer DEL may be disposed on the second interlayer insulating layer 117. The light-emitting diode layer DEL may include an organic light-emitting diode OLED. The organic light-emitting diode OLED may be electrically connected to a sub-pixel circuit PC. The organic light-emitting diode OLED may be electrically connected to the sub-pixel circuit PC to implement a sub-pixel PX. The organic light-emitting diode OLED may include a sub-pixel electrode 210, an emission layer 220, and an opposite electrode 230.

The sub-pixel electrode 210 may be electrically connected to the sub-pixel circuit PC. In an embodiment, as shown in FIG. 4, the sub-pixel circuit PC may be electrically connected to the sub-pixel electrode 210 through a connection electrode CM. In an embodiment, an additional connection electrode may be further disposed between the sub-pixel circuit PC and the sub-pixel electrode 210. The sub-pixel circuit PC and the sub-pixel electrode 210 may be electrically connected to each other through the connection electrode CM and the additional connection electrode. By way of example, the sub-pixel circuit PC and the sub-pixel electrode 210 may be directly electrically connected to each other without the connection electrode CM.

The connection electrode CM may be disposed on the first organic insulating layer 118 and may be connected to the sub-pixel circuit PC through a contact hole formed in the first organic insulating layer 118. The connection electrode CM may include a conductive material including Mo, Al, Cu, Ti, etc. By way of example, the connection electrode CM may include a transparent conductive material, such as transparent conducting oxide (TCO). The connection electrode CM may have a single-layered or multi-layered structure including the aforementioned material.

The first organic insulating layer 118 may include an organic material. For example, the first organic insulating layer 118 may include an organic insulating material, such as a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The second organic insulating layer 119 may be disposed on the connection electrode CM. The second organic insulating layer 119 may include an organic material. For example, the second organic insulating layer 119 may include an organic insulating material, such as acrylic, benzocyclobutene (BCB), polyimide, or hexamethyldisiloxane (HMDSO).

The sub-pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. By way of example, the sub-pixel electrode 210 may further include a conductive oxide layer above and/or below the aforementioned reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the sub-pixel electrode 210 may have a three-layered structure including ITO/Ag/ITO layers.

A bank layer 180 may be disposed on the sub-pixel electrode 210. The bank layer 180 may have an opening that exposes a central portion of the sub-pixel electrode 210. The opening of the bank layer 180 may define an emission area of the organic light-emitting diode OLED, and the emission area of the organic light-emitting diode OLED may correspond to the sub-pixel PX. The bank layer 180 may increase the distance between the edge of the sub-pixel electrode 210 and the opposite electrode 230 above the sub-pixel electrode 210, thereby preventing arcs, etc. from occurring at the edge of the sub-pixel electrode 210.

The bank layer 180 may include an organic insulating material. In an embodiment, the bank layer 180 may include an inorganic insulating material, such as silicon nitride, silicon oxynitride, or silicon oxide. In an embodiment, the bank layer 180 may include an organic insulating material and an inorganic insulating material. In an embodiment, the bank layer 180 may include a light-blocking material and may be provided in a block color. The light-blocking material may include a resin or paste including carbon black, a carbon nano-tube, and a black dye, a metal particle, such as Ni, Al, Mo, and an alloy thereof, a metal oxide particle (for example, chromium oxide), a metal nitride particle (for example, chromium nitride), or the like within the spirit and the scope of the disclosure.

A spacer (not shown) may be disposed on the bank layer 180. The spacer may prevent the organic light-emitting diode OLED from being damaged by sagging of a mask during a manufacturing process using the mask.

The emission layer 220 may be disposed on the sub-pixel electrode 210. The emission layer 220 may overlap the opening of the sub-pixel electrode 210. The emission layer 220 may include a low-molecular or high-molecular material and may emit red, green, blue, or white light.

A functional layer may be further optionally disposed below and above the emission layer 220. For example, a hole injection layer (HIL) and/or a hole transport layer (HTL) may be disposed between the emission layer 220 and the sub-pixel electrode 210. An electron transport layer (ETL) and/or an electron injection layer (EIL) may be disposed between the emission layer 220 and the opposite electrode 230.

In an embodiment, the emission layer 220 may be patterned to correspond to each of the sub-pixel electrodes 210. In an embodiment, the emission layer 220 may be a single body over the sub-pixel electrodes 210. In an embodiment, the functional layer disposed below and above the emission layer 220 may be a single body over the sub-pixel electrodes 210. It is to be understood that single body may also mean integral with each other.

The opposite electrode 230 may be disposed on the emission layer 220. In an embodiment, the opposite electrode 230 may be arranged to entirely cover the display area DA. For example, the opposite electrode 230 may be a single body to cover the sub-pixels PX.

The opposite electrode 230 may include a conductive material with a low work function. For example, the opposite electrode 230 may include a (semi) transparent layer including Ag, Mg, Al, Pt, Pd, Au, Ni, Nd, Ir, Cr, lithium (Li), calcium (Ca), or an alloy thereof. By way of example, the opposite electrode 230 may further include a layer, such as an ITO, IZO, ZnO, or In₂O₃ layer, on the (semi) transparent layer including the aforementioned material.

An encapsulation member may be disposed on the organic light-emitting diode OLED. The encapsulation member may include an encapsulation layer TFE or an encapsulation substrate in the shape of a substrate, such as glass. The encapsulation member may protect the organic light-emitting diode OLED from external moisture and oxygen.

The encapsulation layer TFE may include at least one organic encapsulation layer and at least one inorganic encapsulation layer. The encapsulation layer TFE may entirely cover the display area DA and may be arranged to extend toward the peripheral area PA to cover a portion of the peripheral area PA.

The encapsulation layer TFE may include a first inorganic encapsulation layer 310, a second inorganic encapsulation layer 330 disposed on the first inorganic encapsulation layer 310, and an organic encapsulation layer 320 disposed between the first inorganic encapsulation layer 310 and the second inorganic encapsulation layer 330. The first inorganic encapsulation layer 310 and the second inorganic encapsulation layer 330 may each include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The organic encapsulation layer 320 may include a polymer-based material. The polymer-based material may include acrylic resin, epoxy resin, polyimide, polyethylene, etc. The organic encapsulation layer 320 may include an acrylic resin, such as polymethyl methacrylate or polyacrylic acid. The organic encapsulation layer 320 may be formed by curing a monomer or applying a polymer.

The touch sensor layer 400 may acquire coordinate information according to an external input, for example, a touch event. The touch sensor layer 400 may include a touch electrode and touch wiring lines connected to the touch electrode. The touch sensor layer 400 may detect an external input by using a self-capacitance method or a mutual capacitance method.

The touch sensor layer 400 may be formed on the encapsulation layer TFE. By way of example, the touch sensor layer 400 may be formed separately on a touch substrate and bonded to the encapsulation layer TFE through an adhesive layer, such as optically clear adhesive (OCA). In an embodiment, the touch sensor layer 400 may be formed directly on the encapsulation layer TFE, and the adhesive layer may not be interposed between the touch sensor layer 400 and the encapsulation layer TFE.

The optical functional layer may include an anti-reflection layer. The anti-reflection layer may reduce the reflectance of light (external light) incident on the display panel 10 from the outside. In an embodiment, the optical functional layer may be a polarizing film. By way of example, the optical functional layer may be provided as a filter plate including a black matrix and color filters.

A cover window may be disposed on the display panel 10. The cover window may protect the display panel 10. The cover window may include at least one of glass, sapphire, and plastic. The cover window may be, for example, ultra-thin glass (UTG) or colorless polyimide (CPI).

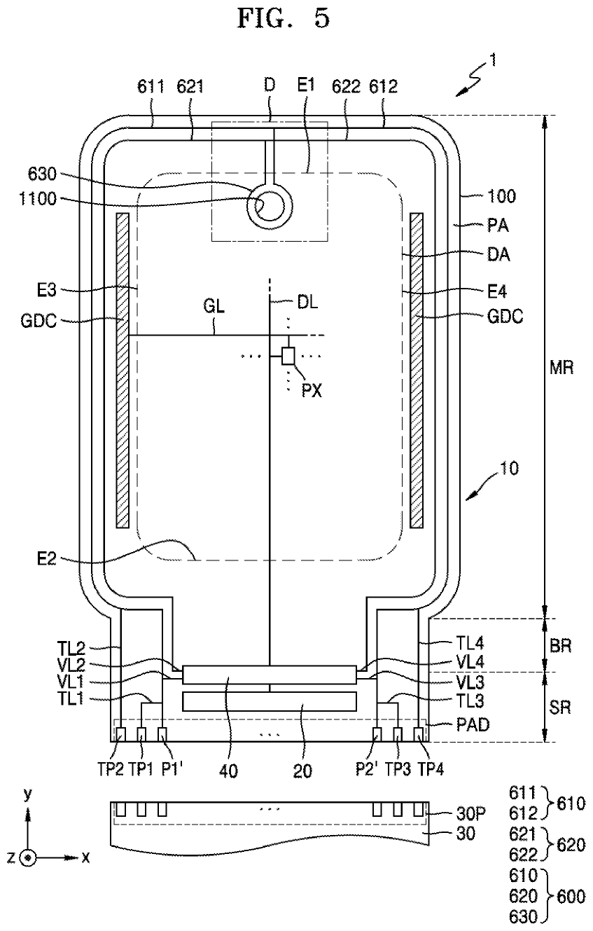

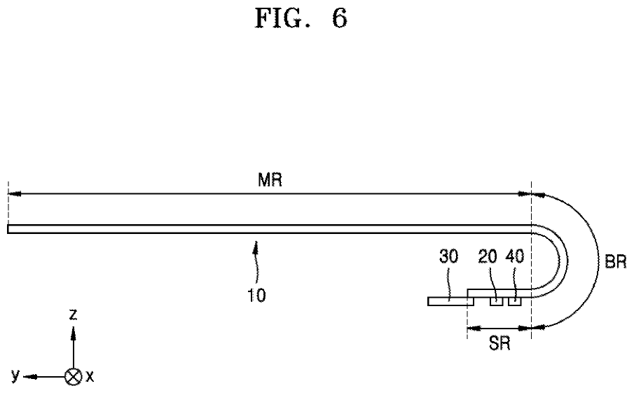

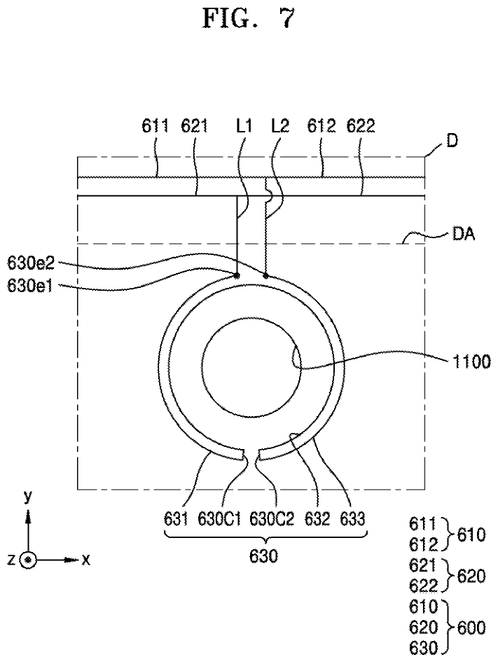

FIG. 5 is a schematic plan view of a display apparatus 1 according to an embodiment, and FIG. 6 is a schematic side view of a display apparatus according to an embodiment. FIG. 7 is an enlarged schematic plan view schematically showing a portion D of the display apparatus 1 of FIG. 5. FIG. 5 is a modified embodiment of FIG. 1, and the following description will focus on differences and descriptions that are redundant with those of the embodiment described above will be omitted.

Referring to FIGS. 5 and 6, a detection circuit 40 may be arranged in the sub-area SR of the display panel 10. In FIG. 5, the detection circuit 40 is shown as being disposed closer to the display area DA than the driving chip 20. However, in an embodiment, the driving chip 20 may be located closer to the display area DA than the detection circuit 40. In an embodiment, the driving chip 20 and the detection circuit 40 may be arranged to overlap each other.

The detection circuit 40 may include voltage lines and transistors. The detection circuit 40 may be electrically connected to a detection line 600 to be described below and may detect cracks by using an electrical signal (for example, voltage value) transmitted from the detection line 600 in case that the display apparatus 1 is driven.

In an embodiment, the detection circuit 40 may be with the display panel 10. For example, the detection circuit 40 may be formed using conductive layers and insulating layers within the display panel 10. In an embodiment, the detection circuit 40 may be provided separately and mounted on the sub-area SR of the display panel 10, such as the driving chip 20 or the printed circuit board 30.

Because the detection circuit 40 is located in the sub-area SR of the display panel 10, as the display panel 10 is bent in the bending area BR, the detection circuit 40 may be located on the rear surface of the main area MR.

Referring to FIGS. 5 and 7, the substrate 100 may include a through hole 1100. The through hole 1100 may be defined within the display area DA. However, because no sub-pixels are formed in and around an area where the through hole 1100 is located, the through hole 1100 may not display an image.

The detection line 600 may be arranged in the peripheral area PA. The detection line 600 may include a first peripheral detection line 610, a second peripheral detection line 620, and a through-hole detection line 630. The first peripheral detection line 610 and the second peripheral detection line 620 may be located outside of the display area DA to surround at least a portion of the display area DA. For example, the first peripheral detection line 610 and the second peripheral detection line 620 may each extend along the first edge E1, the third edge E3, and the fourth edge E4 of the display area DA. The first peripheral detection line 610 may be disposed outside of the second peripheral detection line 620. The second peripheral detection line 620 may be disposed between the first peripheral detection line 610 and the display area DA. An end of each of the first peripheral detection line 610 and the second peripheral detection line 620 may extend to pass through the bending area BR in a direction toward the pad portion PAD. In an embodiment, the first peripheral detection line 610 may be a first line.

At least a portion of the through-hole detection line 630 may be arranged adjacent to the through hole 1100. The first peripheral detection line 610 may be electrically connected to the through-hole detection line 630, and the through-hole detection line 630 may be electrically connected to the second peripheral detection line 620.

The through-hole detection line 630 may be a line for detecting whether a crack has occurred around the through-hole 1100. One end or an end of the through-hole detection line 630 arranged adjacent to the through-hole 1100 may be electrically connected to the first peripheral detection line 610. The other end or another end of the through-hole detection line 630 may be electrically connected to the second peripheral detection line 620.

The first peripheral detection line 610 may include a 1st-1 peripheral detection line 611 and a 1st-2 peripheral detection line 612, and the second peripheral detection line 620 may include a 2nd-1 peripheral detection line 621 and a 2nd-2 peripheral detection line 622. The 1st-1 peripheral detection line 611 and the 2nd-1 peripheral detection line 621 may extend along one side or a side (for example, left) edge of the substrate 100. The 1st-2 peripheral detection line 612 and the 2nd-2 peripheral detection line 622 may extend along the other side or another side (for example, right) edge of the substrate 100.

The through-hole detection line 630 may have a shape that surrounds or dually surrounds the through-hole 1100. The through-hole detection line 630 may include a first part 631, a second part 632, and a third part 633. The first part 631 may surround one side or a side (for example, left side) of the through hole 1100. The second part 632 may be bent from the first part 631 and may entirely surround the through hole 1100. The third part 633 may be bent from the second part 632 and may surround the other side or another side (for example, right side) of the through hole 1100. The through-hole detection line 630 may include a first bent portion 630C1 between the first part 631 and the second part 632 and a second bent portion 630C2 between the second part 632 and the third part 633. The first bent portion 630C1 and the second bent portion 630C2 may face each other and be spaced apart from each other.

One end or an end 630e1 of the through-hole detection line 630 may be electrically connected to the second peripheral detection line 620 through a first connection line L1. The other end 630e2 of the through-hole detection line 630 may be electrically connected to the first peripheral detection line 610 through a second connection line L2.

The detection line 600 may be electrically connected to the pad portion PAD. The pad portion PAD may include a data pad DP, first to fourth test pads TP1, TP2, TP3, and TP4, a first pad P1′, and a second pad P2′. The first pad P1′ may be electrically connected to the 1st-1 peripheral detection line 611 and a first voltage line VL1 to be described below. The second pad P2′ may be electrically connected to the 1st-2 peripheral detection line 612 and a third voltage line VL3.

The detection line 600 may be electrically connected to the detection circuit 40. As shown in FIG. 5, the detection circuit 40 may include the first voltage line VL1, a second voltage line VL2, the third voltage line VL3, and a fourth voltage line VL4. The first voltage line VL1 may be electrically connected to the first pad P1′ and the 1st-1 peripheral detection line 611. The second voltage line VL2 may be electrically connected to the 2nd-1 peripheral detection line 621. A signal transmitted from the first pad P1′ may be transmitted to the 1st-1 peripheral detection line 611 and the first voltage line VL1. In other words, a signal transmitted from the first pad P1′ may pass through the 1st-1 peripheral detection line 611, the through-hole detection line 630, and the 2nd-1 peripheral detection line 621 and be transmitted to the detection circuit 40 through the second voltage line VL2. By way of example, the signal may be directly transmitted to the detection circuit 40 through the first voltage line VL1. Whether a crack has occurred in the display apparatus 1 may be checked based on an electrical signal transmitted through the first voltage line VL1 and an electrical signal transmitted through the second voltage line VL2. The electrical signal may be current and/or voltage.

The third voltage line VL3 may be electrically connected to the second pad P2′ and the 1st-2 detection line 612. The fourth voltage line VL4 may be electrically connected to the 2nd-2 peripheral detection line 622. A signal transmitted from the second pad P2′ may be transmitted to the 1st-2 peripheral detection line 612 and the third voltage line VL3. In other words, a signal transmitted from the second pad P2′ may pass through the 1st-2 peripheral detection line 612, the through-hole detection line 630, and the 2nd-2 peripheral detection line 622 and be transmitted to the detection circuit 40 through the fourth voltage line VL4. By way of example, the signal may be directly transmitted to the detection circuit 40 through the third voltage line VL3. Whether a crack has occurred in the display apparatus 1 may be checked based on an electrical signal transmitted through the third voltage line VL3 and an electrical signal transmitted through the fourth voltage line VL4. In an embodiment, the same electrical signal may be applied to the first pad P1′ and the second pad P2′ at the same time.

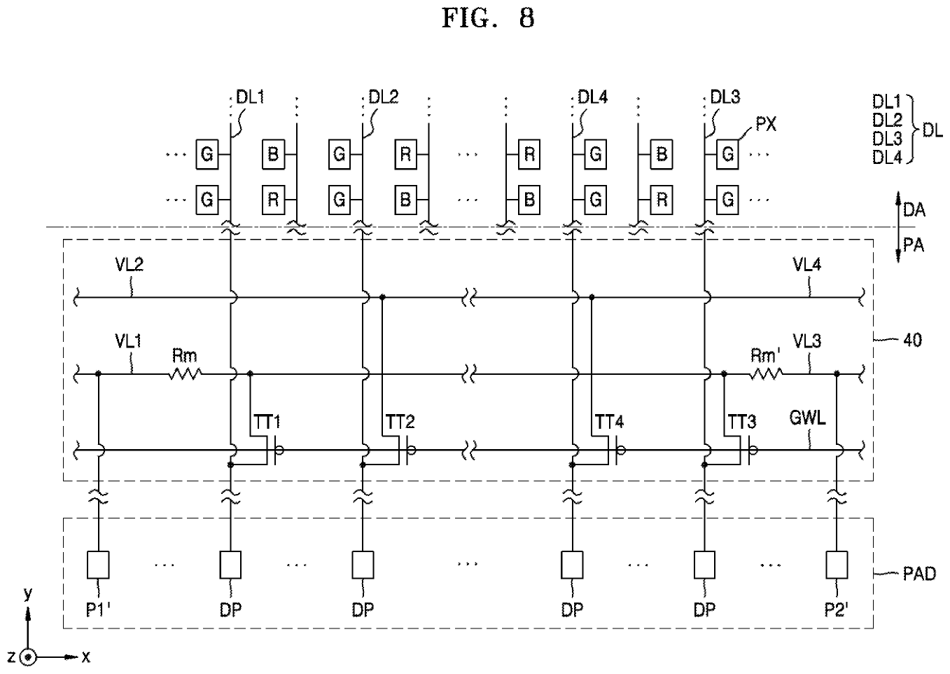

FIG. 8 is an enlarged schematic plan view of the detection circuit 40 of the display apparatus 1 of FIG. 5. In FIG. 8, some or a number of the sub-pixels PX and some or a number of the data lines DL arranged on the display panel 10 are shown for convenience of description.

Referring to FIG. 8, the sub-pixels PX may include a red sub-pixel R that emits red light, a blue sub-pixel B that emits blue light, and a green sub-pixel G that emits green light. Red sub-pixels R and blue sub-pixels B may be alternately arranged in the same column, and green sub-pixels G may be arranged, in a line, in a column adjacent to a column in which the red sub-pixels R and the blue sub-pixels B are arranged. In an embodiment, the red sub-pixels R and the blue sub-pixels B may be alternately arranged so as not to be repeatedly arranged in the same column in two adjacent rows. It is shown in FIG. 8 that the sub-pixels PX include a red sub-pixel R, a blue sub-pixel B, and a green sub-pixel G. However, the sub-pixels PX may further include a pixel of a color other than red, green, and blue. Additional colors may be included.

The data lines DL may be arranged in each column. The data lines DL may be respectively connected to data pads DP of the pad portion PAD. Among the data lines DL, a data line connected to the first voltage line VL1 of the detection circuit 40 may be referred to as a first data line DL1, a data line connected to the second voltage line VL2 of the detection circuit 40 may be referred to as a second data line DL1, a data line connected to the third voltage line VL3 of the detection circuit 40 may be referred to as a third data line DL3, and a data line connected to the fourth voltage line VL4 of the detection circuit 40 may be referred to as a fourth data line DL4.

It is shown in FIG. 8 that there is one first data line DL1 connected to the first voltage line VL1. However, in an embodiment, there may be first data lines DL1 connected to the first voltage line VL1. Although the explanation is based on the first data line DL1, the same may be applied to the third data line DL3. For example, there may be third data lines DL3 connected to the third voltage line VL3. It is shown in FIG. 8 that the sub-pixels PX connected to the first data line DL1 are green sub-pixels G. However, in an embodiment, the sub-pixels PX connected to the first data line DL1 may be red sub-pixels R and/or green sub-pixels G. Although the explanation is based on the first data line DL1, the same may be applied to the third data line DL3.

The detection circuit 40 may include the first voltage line VL1, the second voltage line VL2, the third voltage line VL3, the fourth voltage line VL4, a first transistor TT1, a second transistor TT2, a third transistor TT3, and a fourth transistor TT4.

The first transistor TT1 may include a first terminal connected to the first voltage line VL1, a second terminal connected to the first data line DL1, and a gate. The first transistor TT1 may be turned on by a control signal applied to the gate and connect the first voltage line VL1 to the first data line DL1.

The second transistor TT2 may include a first terminal connected to the second voltage line VL2, a second terminal connected to the second data line DL2, and a gate. The second transistor TT2 may be turned on by a control signal applied to the gate and connect the second voltage line VL2 to the second data line DL2.

The third transistor TT3 may include a first terminal connected to the third voltage line VL3, a second terminal connected to the third data line DL3, and a gate. The third transistor TT3 may be turned on by a control signal applied to the gate and connect the third voltage line VL3 to the third data line DL3.

The fourth transistor TT4 may include a first terminal connected to the fourth voltage line VL4, a second terminal connected to the fourth data line DL4, and a gate. The fourth transistor TT4 may be turned on by a control signal applied to the gate and connect the fourth voltage line VL4 to the fourth data line DL4.

In an embodiment, the gate of each of the first to fourth transistors TT1, TT2, TT3, and TT4 may be a part of a first gate line GWL and integral. The first gate line GWL may be electrically connected to the driving chip 20. The first to fourth transistors TT1, TT2, TT3, and TT4 may be simultaneously controlled. In other words, the first to fourth transistors TT1, TT2, TT3, and TT4 may be turned on or off at the same time by the same control signal. For example, while the printed circuit board 30 is attached to the pad portion PAD and a data signal is applied to the data pad DP, the first to fourth transistors TT1, TT2, TT3, and TT4 may be operated by the same control signal.

The detection circuit 40 may include matching resistors Rm and Rm′. The matching resistor Rm may be connected to the first voltage line VL1. The matching resistance Rm may be set considering the resistance of a loop that passes through the 1st-1 peripheral detection line 611, the through-hole detection line 630, and the 2nd-1 peripheral detection line 621 and reaches the second voltage line VL2. Similarly, the matching resistor Rm′ may be connected to the third voltage line VL3. The matching resistance Rm′ may be set considering the resistance of a loop that passes through the 1st-2 peripheral detection line 612, the through-hole detection line 630, and the 2nd-2 peripheral detection line 622 and reaches the fourth voltage line VL4.

The detection circuit 40 may predict whether a crack occurs in the display apparatus 1 and/or the display panel 10 as follows.

For example, a black data voltage may be applied to the first pad P1 and the second pad P2′. In case that no crack occurs, an electrical signal transmitted through the 1st-1 peripheral detection line 611, the through-hole detection line 630, the 2nd-1 peripheral detection line 621, and the second voltage line VL2 and an electrical signal transmitted through the first voltage line VL1 may be the same as a black data voltage. An electrical signal transmitted through the 1st-2 peripheral detection line 612, the through-hole detection line 630, the 2nd-2 peripheral detection line 622, and the fourth voltage line VL4 and an electrical signal transmitted through the third voltage line VL3 may be the same as a black data voltage.

Accordingly, the first data line DL1 connected to the first voltage line VL1 by the first transistor TT1 receives a black data voltage, and sub-pixels PX connected to the first data line DL1 receive the black data voltage and do not emit light. Similarly, the second data line DL2 connected to the second voltage line VL2 by the second transistor TT2 receives a black data voltage, and sub-pixels PX connected to the second data line DL2 receive the black data voltage and do not emit light. The third data line DL3 connected to the third voltage line VL3 by the third transistor TT3 receives a black data voltage, and sub-pixels PX connected to the third data line DL3 receive the black data voltage and do not emit light. The fourth data line DL4 connected to the fourth voltage line VL4 by the fourth transistor TT4 receives a black data voltage, and sub-pixels PX connected to the fourth data line DL4 receive the black data voltage and do not emit light.

In case that a crack occurs and the 2nd-1 peripheral detection line 621 is disconnected, an electrical signal transmitted through the second voltage line VL2 may be higher or lower than the black data voltage. Accordingly, the second data line DL2 connected to the second voltage line VL2 by the second transistor TT2 receives a voltage different from the black data voltage, and the sub-pixels PX connected to the second data line DL2 emit light. The sub-pixels PX connected to each of the first data line DL1, the third data line DL3, and the fourth data line DL4 do not emit light.

In case that a crack occurs and the 2nd-2 peripheral detection line 622 is disconnected, an electrical signal transmitted through the fourth voltage line VL4 may be higher or lower than the black data voltage. Accordingly, the fourth data line DL4 connected to the fourth voltage line VL4 by the fourth transistor TT4 receives a voltage different from the black data voltage, and the sub-pixels PX connected to the fourth data line DL4 emit light. The sub-pixels PX connected to each of the first data line DL1, the second data line DL2, and the third data line DL3 do not emit light.

In case that a crack occurs and the through-hole detection line 630 is disconnected, or both the 2nd-1 peripheral detection line 621 and the 2nd-2 peripheral detection line 622 are disconnected, the electrical signal transmitted through the second voltage line VL2 and the electrical signal transmitted through the fourth voltage line VL4 may be higher or lower than the black data voltage. Accordingly, the second data line DL2 connected to the second voltage line VL2 by the second transistor TT2 and the fourth data line DL4 connected to the fourth voltage line VL4 by the fourth transistor TT4 receive a voltage different from the black data voltage, and the sub-pixels PX connected to the second data line DL2 and the fourth data line DL4 emit light. The sub-pixels PX connected to each of the first data line DL1 and the third data line DL3 do not emit light.

However, in case that a crack occurs and the 1st-1 peripheral detection line 611 is disconnected, an electrical signal transmitted from the second pad P2′ through the 1st-2 peripheral detection line 612 may be transmitted through the 2nd-1 peripheral detection line 621 and the second voltage line VL2. The first voltage line VL1 may be directly connected to the first pad P1′. Accordingly, an electrical signal transmitted through the second voltage line VL2 and an electrical signal transmitted through the first voltage line VL1 may be the same as a black data voltage. Similarly, in case that a crack occurs and the 1st-2 peripheral detection line 612 is disconnected, an electrical signal transmitted from the first pad P1′ through the 1st-1 peripheral detection line 611 may be transmitted through the 2nd-2 peripheral detection line 622 and the fourth voltage line VL4. The third voltage line VL3 may be directly connected to the second pad P2′. An electrical signal transmitted through the fourth voltage line VL4 and an electrical signal transmitted through the third voltage line VL3 may be the same as a black data voltage. Accordingly, the sub-pixels PX connected to each of the first data line DL1, the second data line DL2, the third data line DL3, and the fourth data line DL4 may not emit light.

According to the detection circuit 40 described above, not only whether a crack has occurred in the display apparatus 1, but also the location where the crack has occurred may be predicted depending on whether the sub-pixels PX connected to the first data line DL1 to the fourth data line DL4 emit light. However, the detection circuit 40 may not detect a crack in the display apparatus 1 in a non-driving state, and may not detect a crack occurring in the 1st-1 peripheral detection line 611 or the 1st-2 peripheral detection line 612 among the detection lines 600.

Referring to FIG. 5, the display apparatus 1 may include first to fourth test pads TP1, TP2, TP3, and TP4 and first to fourth test lines TL1, TL2, TL3, and TL4.0

The first to fourth test pads TP1, TP2, TP3, and TP4 may be electrically connected to the first test line TL1, the second test line TL2, the third test line TL3, and the fourth test line TL4, respectively. The first to fourth test pads TP1, TP2, TP3, and TP4 may be pads for transmitting test signals or measuring loop resistance.

The first peripheral detection line 610 may be electrically connected to the first to fourth test lines TL1, TL2, TL3, and TL4. The first test line TL1 may be electrically connected to the 1st-1 peripheral detection line 611 in the sub-area SR, for example, between the bending area BR and the pad portion PAD. The first test line TL1 may electrically connect the 1st-1 peripheral detection line 611 to the first test pad TP1.

The second test line TL2 may extend from the pad portion PAD toward the display area DA to pass through the bending area BR. The second test line TL2 may be electrically connected to the 1st-1 peripheral detection line 611 in the main area MR, for example, between the bending area BR and the display area DA. The second test line TL2 may electrically connect the 1st-1 peripheral detection line 611 to the second test pad TP2.

The third test line TL3 may be electrically connected to the 1st-2 peripheral detection line 612 in the sub-area SR, for example, between the bending area BR and the pad portion PAD. The third test line TL3 may electrically connect the 1st-2 peripheral detection line 612 to the third test pad TP3.

The fourth test line TL4 may extend from the pad portion PAD toward the display area DA to pass through the bending area BR. The fourth test line TL4 may be electrically connected to the 1st-2 peripheral detection line 612 in the main area MR, for example, between the bending area BR and the display area DA. The fourth test line TL4 may electrically connect the 1st-2 peripheral detection line 612 to the fourth test pad TP4.

According to an embodiment of the disclosure, whether a crack has occurred in the display apparatus 1 may be checked even in a non-driving state through the first to fourth test lines TL1, TL2, TL3, and TL4 and the first to fourth test pads TP1, TP2, TP3, and TP4, connected to the first peripheral detection line 610.

For example, the first test line TL1, a portion of the first peripheral detection line 610, and the third test line TL3 may be connected to each other to surround the display area DA and may form a first pattern having a loop shape with one side or a side open. The loop resistance value of the first pattern may be measured through the first test pad TP1 and the third test pad TP3. In case that a crack occurs in the first pattern, the resistance value of the first pattern may be measured to be greater than a preset resistance value. Whether a crack has occurred in the display apparatus 1 may be checked through a change in the resistance value of the first pattern.

The first test line TL1, a portion of the first peripheral detection line 610, and the second test line TL2 may be connected to each other and form a second pattern in the form of a loop that passes through the left bending area BR and is open on one side or a side. The loop resistance value of the second pattern may be measured through the first test pad TP1 and the second test pad TP2. In case that a crack occurs in the second pattern, the resistance value of the second pattern may be measured to be greater than a preset resistance value. Through the change in the resistance value of the second pattern, it may be checked whether a crack has occurred in the bending area BR of the display apparatus 1, by way of example, in the left bending area BR.

The third test line TL3, a portion of the first peripheral detection line 610, and the fourth test line TL4 may be connected to each other and form a third pattern in the form of a loop that passes through the right bending area BR and is open on one side or a side. The loop resistance value of the third pattern may be measured through the third test pad TP3 and the fourth test pad TP4. In case that a crack occurs in the third pattern, the resistance value of the third pattern may be measured to be greater than a preset resistance value. Through the change in the resistance value of the third pattern, it may be checked whether a crack has occurred in the bending area BR of the display apparatus 1, by way of example, in the right bending area BR.

As the display apparatus 1 according to an embodiment may include the first to fourth test lines TL1, TL2, TL3, and TL4 and the first to fourth test pads TP1, TP2, TP3, and TP4, connected to the first peripheral detection line 610 extending to surround the display area DA, it may be checked whether a crack has occurred in the display apparatus 1 in a non-driving state. For example, it may be checked whether a crack has occurred in the left or right bending area BR of the display apparatus 1. Even in case that the display apparatus 1 is driven, it may be checked whether a crack of the first peripheral detection line 610, that may not be detected by the detection circuit 40, has occurred in the first peripheral detection line 610.

According to an embodiment as described above, a display apparatus capable of detecting cracks in a non-driving state and detecting cracks at each process level during a manufacturing process may be implemented. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display apparatus comprising:
a first area including a display area, a second area, and a bending area disposed between the first area and the second area;
a substrate;
a display element disposed on the substrate in the display area;
a first line extending to surround at least a portion of the display area;
a first test pad, a second test pad, and a third test pad, disposed in the second area;
a first test line electrically connected to the first line in the second area and electrically connected to the first test pad;
a second test line extending through the bending area, the second test line being electrically connected to the first line in the first area, and the second test line being electrically connected to the second test pad; and
a third test line spaced apart from the first test line, the third test line being electrically connected to the first line in the second area, and the third test line being electrically connected to the third test pad.

2. The display apparatus of claim 1, wherein the substrate is bent in the bending area, and a back surface of the second area faces at least a portion of a back surface of the first area.

3. The display apparatus of claim 1, further comprising:
a fourth test pad disposed in the second area; and
a fourth test line extending through the bending area, the fourth test line being electrically connected to the first line in the first area, and the fourth test line being electrically connected to the fourth test pad.

4. The display apparatus of claim 3, wherein
the first test line and the second test line are disposed on a side of the substrate, and
the third test line and the fourth test line are disposed on another side of the substrate opposite to the side of the substrate.

5. The display apparatus of claim 1, wherein the first line, the first test line, the second test line, and the third test line are integral with each other.

6. The display apparatus of claim 1, wherein
the substrate has a through hole included in the first area, and
the display apparatus further comprises:
a through-hole detection line electrically connected to the first line and adjacent to the through hole; and
a second line electrically connected to the through-hole detection line and extending to surround at least a portion of the display area.

7. The display apparatus of claim 6, wherein the through-hole detection line has a shape that surrounds or dually surrounds the through hole.

8. The display apparatus of claim 6, wherein the first line is disposed outside of the second line.

9. The display apparatus of claim 6, wherein
the first line includes a 1st-1 line extending along an edge of the substrate and a 1st-2 line extending along another edge of the substrate, and
the second line includes a 2nd-1 line extending along an edge of the substrate and a 2nd-2 line extending along another edge of the substrate.

10. The display apparatus of claim 9, further comprising:
a first pad disposed in the second area;
a first voltage line electrically connected to the first pad; and
a second voltage line electrically connected to the 2nd-1 line.

11. The display apparatus of claim 10, wherein the 1st-1 line is electrically connected to the first pad.

12. The display apparatus of claim 10, further comprising:
a first data line and a second data line disposed in the display area, each of the first data line and the second data line extending in a first direction;
a first transistor electrically connected between the first voltage line and the first data line; and
a second transistor electrically connected between the second voltage line and the second data line.

13. The display apparatus of claim 12, wherein the first transistor and the second transistor are simultaneously controlled.

14. The display apparatus of claim 9, further comprising:
a second pad disposed in the second area;
a third voltage line electrically connected to the second pad; and
a fourth voltage line electrically connected to the 2nd-2 line.

15. The display apparatus of claim 14, wherein the 2nd-1 line is electrically connected to the second pad.

16. The display apparatus of claim 14, further comprising:
a third data line and a fourth data line disposed in the display area and each of the third data line and the fourth data line extending in a first direction;
a third transistor electrically connected between the third voltage line and the third data line; and
a fourth transistor electrically connected between the fourth voltage line and the fourth data line.

17. The display apparatus of claim 16, wherein the third transistor and the fourth transistor are simultaneously controlled.

18. The display apparatus of claim 9, further comprising:
a fourth test pad disposed in the second area; and
a fourth test line extending through the bending area, the fourth test line being electrically connected to the first line in the first area, and the fourth test line being electrically connected to the fourth test pad.

19. The display apparatus of claim 18, wherein
the first test line and the second test line are electrically connected to the 1st-1 line, and
the third test line and the fourth test line are electrically connected to the 1st-2 line.

20. The display apparatus of claim 19, wherein
The first test line and the second test line are disposed on a side of the substrate, and
the third test line and the fourth test line are disposed on another side of the substrate opposite to the side of the substrate.
